(19) United States
(12) Patent Application Publication
(10) Pub. No.: US 2011/0278633 A1
(43) Pub. Date: Nov. 17, 2011

(54) LED Light Bulb With Integrated Heat Sink

(76) Inventor: Scott Allen Clifford, Mesa, AZ (US)

(21) Appl. No.: 13/105,888

(22) Filed: May 11, 2011

Related U.S. Application Data
(60) Provisional application No. 61/333,672, filed on May 11, 2010.

(51) Int. Cl. H01L 33/64

(52) U.S. Cl. 257/99; 257/E33.066

(57) ABSTRACT

The use of an LED light source coupled with an integrated heat sink is described in this application. The most preferred embodiments of the present invention comprise an LED light source surrounded by a plurality of heat vanes, with each heat vane comprising a plurality of heat fins, all positioned to dissipate heat in an enclosure housing the LED light source. In at least some preferred embodiments of the present invention, a pair of waterproof tubes are used to house a pair of electrical conductors that are used to connect the LED light source to a power source. The most preferred embodiments of the present invention further comprise a single LED contained in a housing fitted with a compound parabolic concentrator configuration.

### RELATED APPLICATIONS

This application claims priority under 35 U.S.C. §119 (e) to the filing date of U.S. Provisional Patent Application Ser. No. 61/333,672, entitled “LED Light Bulb With Integrated Heat Sink,” which application was filed on May 11, 2010 and the disclosure of which is incorporated herein by reference.

### BACKGROUND OF THE INVENTION

1. Technical Field

The present invention relates to the use of light emitting diodes (LEDs) in light bulbs and more particularly relates to heat dissipation in LED light bulbs.

2. Background Art

The life of an LED depends on the heat of its environment. Above a certain temperature, the lifespan of the LED bulb may be significantly shortened.

### BRIEF SUMMARY OF THE INVENTION

The use of an LED light source coupled with an integrated heat sink is described in this application. The most preferred embodiments of the present invention comprise an LED light source surrounded by a plurality of heat vanes, with each heat vane comprising a plurality of heat fins, all positioned to dissipate heat in an enclosure housing the LED light source. In at least some preferred embodiments of the present invention, a pair of waterproof tubes are used to house a pair of electrical conductors that are used to connect the LED light source to a power source. The most preferred embodiments of the present invention further comprise a single LED contained in a housing fitted with a compound parabolic concentrator configuration.

### BRIEF DESCRIPTION OF THE FIGURES

The preferred embodiments of the present invention will hereinafter be described in conjunction with the appended drawings, wherein like designations denote like elements, and:

FIG. 1 depicts an LED light bulb with an integrated heat sink in accordance with a preferred embodiment of the present invention;

FIG. 2 depicts a heat sink array configuration for use in conjunction with an LED light bulb with an integrated heat sink in accordance with a preferred embodiment of the present invention;

FIG. 3 depicts a single heat sink vane for use in conjunction with an LED light bulb with an integrated heat sink in accordance with a preferred embodiment of the present invention;

FIG. 4 depicts a heat sink vane attached to a heat sink plug for use in conjunction with an LED light bulb with an integrated heat sink in accordance with a preferred embodiment of the present invention;

FIG. 5 depicts a sectional view of a protective housing containing a heat sink assembly for use in conjunction with an LED light bulb with an integrated heat sink in accordance with a preferred embodiment of the present invention;

FIG. 6 depicts a heat sink assembly for use in conjunction with an LED light bulb with an integrated heat sink in accordance with a preferred embodiment of the present invention;

FIG. 7 depicts a top view of a collared connector for use in conjunction with an LED light bulb with an integrated heat sink in accordance with a preferred embodiment of the present invention;

FIG. 8 depicts a side view of a collared connector for use in conjunction with an LED light bulb with an integrated heat sink in accordance with a preferred embodiment of the present invention; and

FIG. 9 depicts an LED light bulb with an integrated heat sink in accordance with a preferred embodiment of the present invention.

### DETAILED DESCRIPTION

The use of an LED light source coupled with an integrated heat sink is described in this application. The most preferred embodiments of the present invention comprise an LED light source surrounded by a plurality of heat vanes, with each heat vane comprising a plurality of heat fins, all positioned to dissipate heat in an enclosure housing the LED light source. In at least some preferred embodiments of the present invention, a pair of waterproof tubes are used to house a pair of electrical conductors that are used to connect the LED light source to a power source. The most preferred embodiments of the present invention further comprise a single LED contained in a housing fitted with a compound parabolic concentrator configuration.

At least one preferred embodiment of the present invention may include a singularity or a plurality of heat vanes attached to a plug in an array configuration.

In certain preferred embodiment, a plurality of vanes may be arranged in a circular array or any other array configuration. In certain preferred embodiment, the array of fins may be below the LED mounting, but others may include a plurality of heat vanes and fins surrounding the mounting and, at least partially surrounding the LED light source.

Particular preferred embodiments also include LED light bulbs attached to heat sinks to dissipate heat. The various preferred embodiments may be manufactured using conventional procedures known to those of ordinary skill in the art as added to and improved upon through the procedures described here.

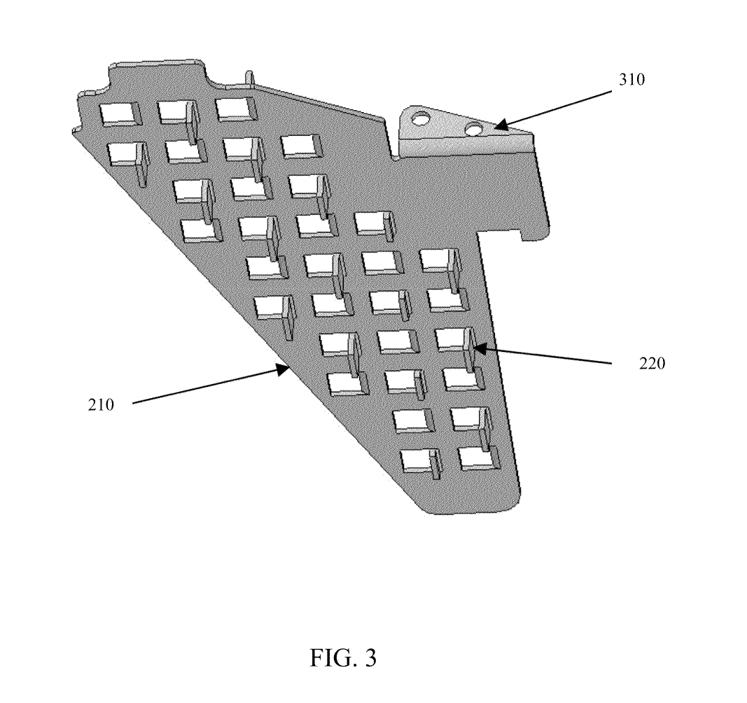

Implementations of the preferred embodiment of the present invention may comprise from one to a plurality of heat vanes and/or smaller heat fins to increase the rate of effective heat transfer away from the LED light source. The various preferred embodiment of the present invention will typically comprise heat vanes and/or the heat fins may have any geometry that is conductive to effective heat transfer. In certain preferred embodiments of the present invention, the heat fins may have a rectangular array pattern such as shown in FIG. 3, though other preferred embodiments may have different array patterns. In certain preferred embodiments that include arrays, though arrays are not required in every preferred embodiment, the heat fins may be integrally formed with the heat vanes and bent out of the heat vanes at approximately a 90° angle while in other preferred embodiments the heat fins may be attached by any other method, or even maintained in-line with the remainder of the vanes. It is specifically contemplated that the heat sink vanes may be made of any highly heat conductive material, such as a metallic material like copper or nickel-plated aluminum. The heat sink plug may also be made of a highly heat conductive material. In certain preferred embodiments, the heat sink plug is made of copper and the one or more heat vanes is made of nickel-plated aluminum.

Various configurations of the device may have parts attached through mechanical fasteners, solder, resins, or other attachment methods. In certain preferred embodiments, the heat vanes may be soldered to the plug to increase the thermal contact between the vane and the plug. The soldered assembly may be heat treated to encourage even solder flow between the heat vane's attachment surface and the heat sink plug, and to improve the consistency of the thermal properties throughout the bulb. Other preferred embodiments may include other methods of attachment such as press fitting, resins, or other mechanical methods. The plug may be attached to zero, one, or more other layers between the plug and the chip on which the LED's are mounted by any of the aforementioned attachment methods.

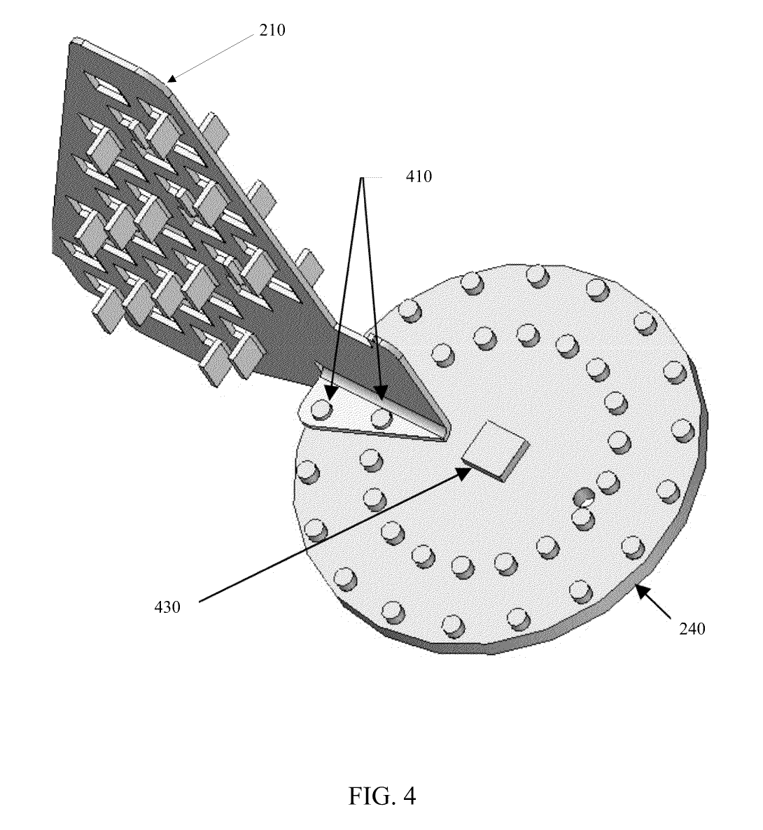

Certain preferred embodiments of a LED light bulb in may comprise a heat sink plug. The heat sink plug may have a feature to orient the heat sink on the mounting feature of the bulb, such as, but not limited to pins, slots, a keyed pin, or a shaped pin, such as the square pin seen in FIG. 4. Certain preferred embodiments of the present invention may include pegs, slots, or other features on the plug that allow for orientation and attachment of the vanes. Other preferred embodiments may include other methods of attachment of the vane to the plug, including, but not limited to soldering without mechanical attachment, mechanical attachment only, or casting a complete part instead of assembling it.

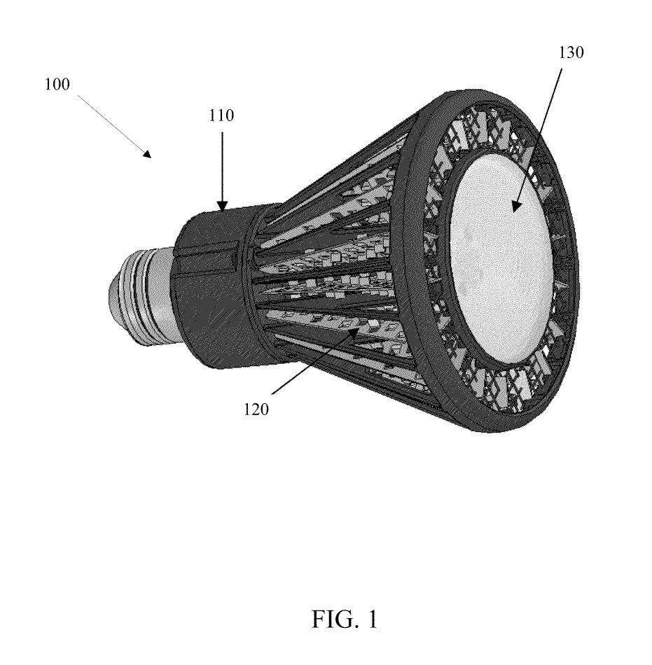

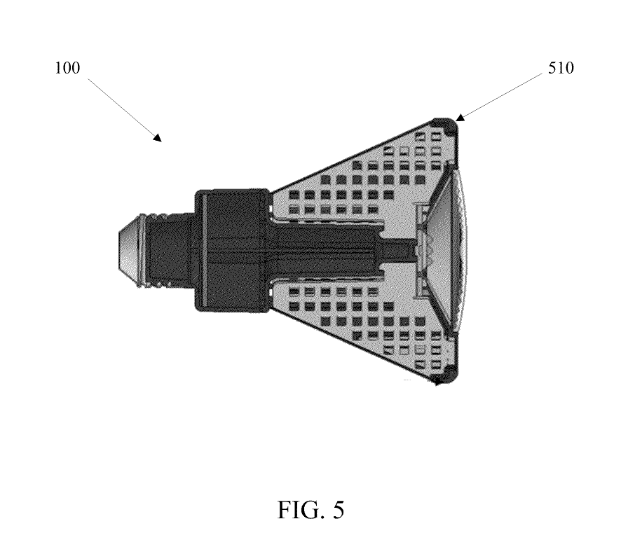

Various preferred embodiments of the device may include a protective casing around the LED mount, the heat sink, the heat vanes, and any combination of these and any other part on the LED light bulb. Certain preferred embodiments of the device may include a meshed structure, a circular array of beams, or any combination of these or any other structural method of a protective casing, such as seen in FIG. 1. Certain implementations may include a protective hoop around the LED bulb such as seen in FIG. 5. For example, a thick plastic ring may surround the top of a can light where the bulb is widest in diameter.

Certain LED light bulbs in accordance with a preferred embodiment of the present invention may include a separate plastic casing for the electrical housing and the heat sink casing. Other preferred embodiments may include a single part for the casing while others may have several parts. The casing may be attached by any method including but not limited to mechanical fasteners or epoxies. The electrical housing may include electrical conduits that lead to the LED mounting and in particular configurations may lead to an interface feature to mount into a light fixture, such as a standard bulb end for screwing the LED light bulb into a standard bulb socket.

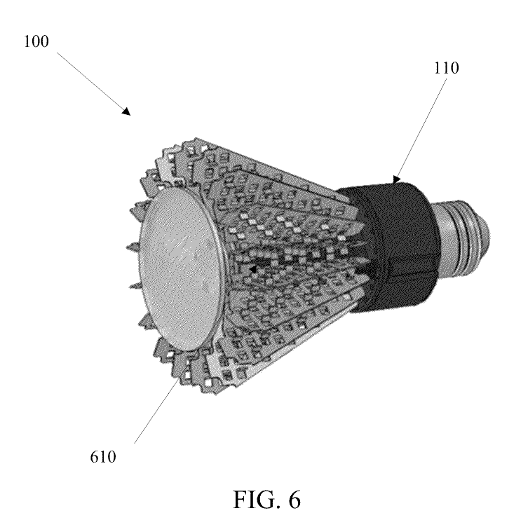

Certain preferred embodiments of the LED light bulb may include a separate, sealed section containing a LED source, such as in FIG. 5 and FIG. 6. Features of these implementations may include any combination of reflective focusing shapes and surfaces such as a parabolic or hyperbolic surfaces. These implementations may also be capped with a transparent surface such as but not limited to a Fresnel lens, simple lens, window, or compound lens. In certain implementations of the device, the lens may be solid; however other implementations may include a fluid lens or another type of transparent aperture.

The components used for a LED light bulb with an integrated heat sink in accordance with a preferred embodiment of the present invention, such as those shown herein, may be made of conventional materials used to make goods similar to these in the art, such as, by non-limiting example, zinc-coated aluminum, copper, other metals, glass, polycarbonate, polyvinylchloride (PVC) or other rigid or flexible rubbers, plastics, or resins. Those of ordinary skill in the art will readily be able to select appropriate materials and manufacture the LED light bulbs of the present invention from the disclosures provided herein.

Referring now to FIG. 1, an LED light bulb 100 with an integrated heat sink in accordance with a preferred embodiment of the present invention comprises a bulb housing or casing 110, an LED encasement 130, and an integrated heat sink assembly 120. Bulb housing or casing 110 is most preferably manufactured from a heat-resistant resilient plastic material. LED encasement 130 covers and protects an LED light source housed within the interior space defined by bulb housing or casing 110. Bulb housing or casing 110 typically is a molded plastic element but those skilled in the art will recognize that other suitable types of manufacturing processes and materials may be used. LED encasement 130 is any suitably durable material that may serve as a substantially transparent yet protective covering. For example, in the most preferred embodiments of the present invention, heat-resistant, clear, hard plastic materials will be used for LED encasement 130.

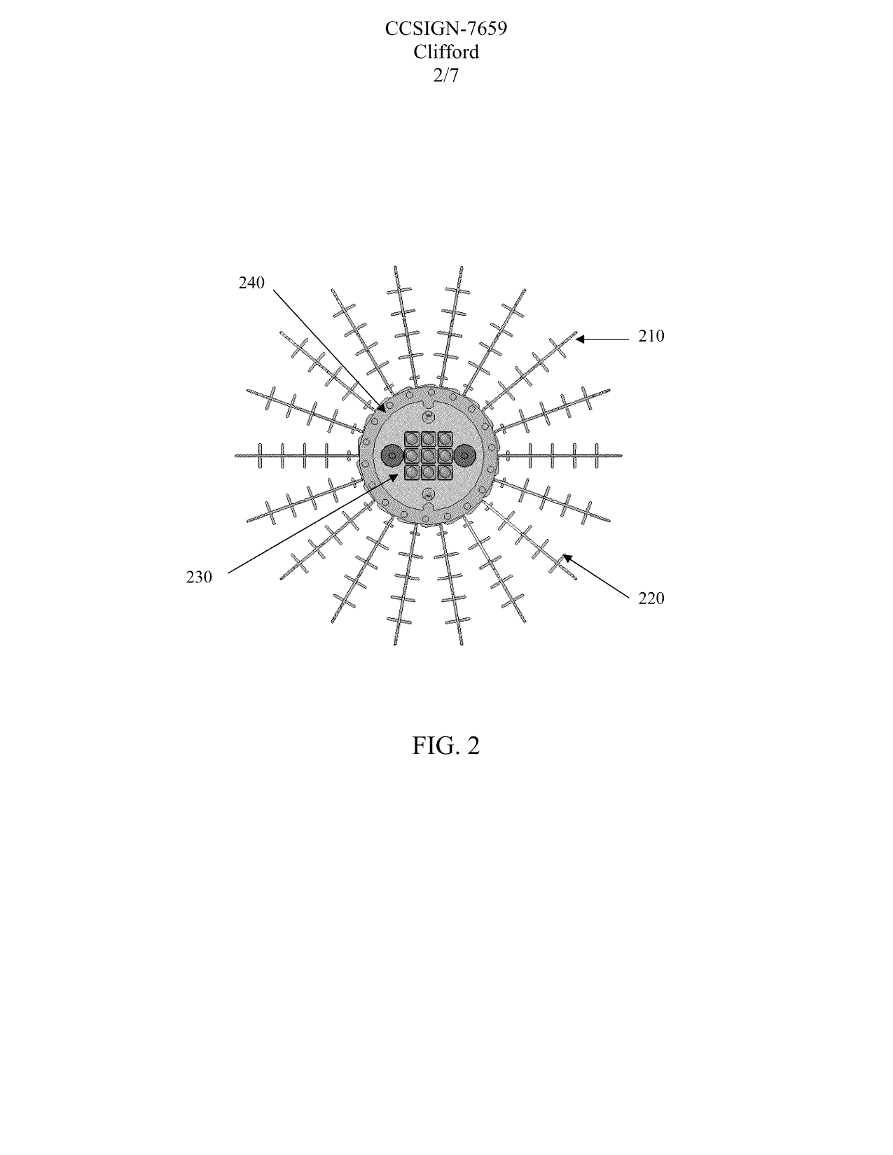

Referring now to FIG. 2, a heat sink array configuration for use in conjunction with an LED light bulb with an integrated heat sink in accordance with a preferred embodiment of the present invention comprises a plurality of heat vanes 210, a plurality of heat fins 220, an LED mount 230, and a heat sink plug 240. As shown in FIG. 2, heat vanes 210 may be arranged in a substantially circular array encircling LED mount 230 and, by extension, the associated LED light source. While the array of heat vanes depicted in FIG. 2 is the most preferred embodiment for the arrangement of the heat vanes, those skilled in the art will appreciate that other configurations are also possible. Each heat fin 220 is most preferably configured so as to form a right angle (e.g. be perpendicular with) the surface area or plane that is associated with their respective heat vane 210. LED mount 230 provides a surface area for mounting an LED light source. In the most preferred embodiments of the present invention, a single LED light is used as the LED light source. However, those skilled in the art will recognize that LED mount 230 may be configured to accommodate virtually any number and types of LED light sources.

Referring now to FIG. 3, a single heat sink vane 210 for use in conjunction with an LED light bulb with an integrated heat sink in accordance with a preferred embodiment of the present invention comprises an attachment surface 310. Attachment surface 310 may be configured so as to allow each heat sink vane 210 to be mounted to the top surface of heat sink plug 240 or the bottom surface of heat sink plug 240. In addition, each heat sink vane 210 will allow for heat sink fins 220 to be positioned above and below the LED light source. As shown in FIG. 3, heat sink fins 220 are formed by creating opening 3-sided rectangular apertures in heat sink vane 210 and bending the heat sink fin outward at a 90° angle. Other configurations that are designed to accomplish the same purpose (e.g., position heat sink fins 220 at an angle relative to heat sink vanes 210) will also be possible.

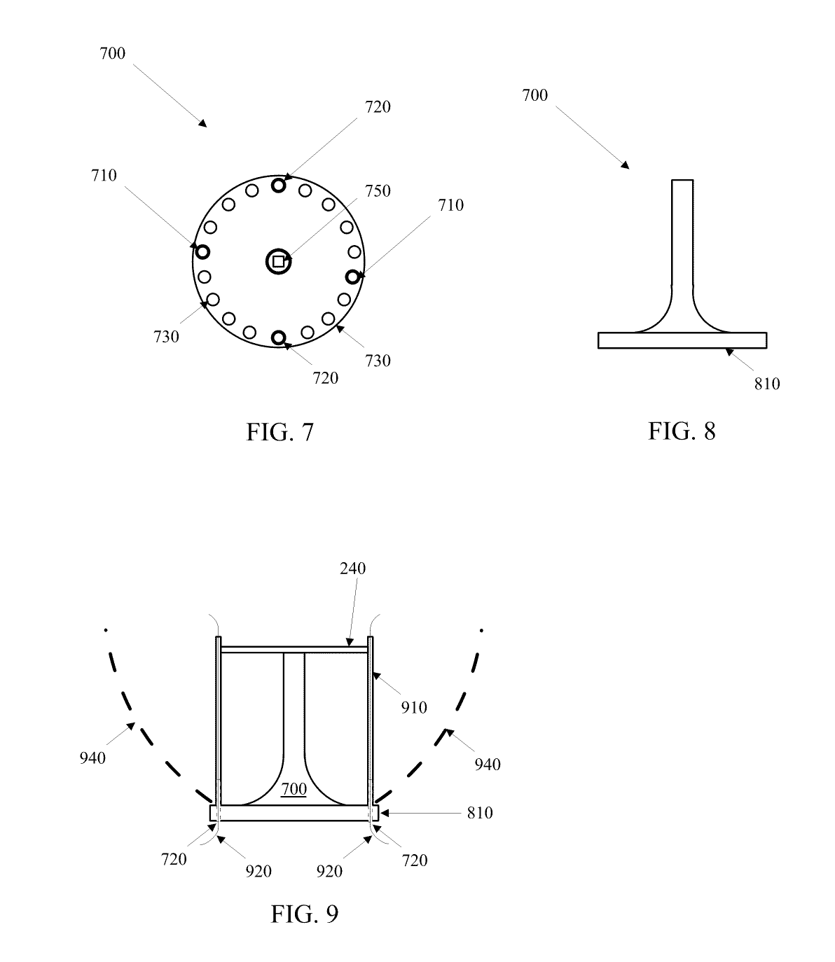

Referring now to FIG. 4, a heat sink vane 210 is attached to a heat sink plug 240 for use in conjunction with an LED light bulb with an integrated heat sink in accordance with a preferred embodiment of the present invention comprises a plurality of heat vane attachment pins 410. Heat vane attachment pins 410 are used to align each heat sink vane 210 for attachment to heat sink plug 240. In addition, a plug orientation pin 430 is included. This provides alignment for the collared connector as shown in FIG. 7, FIG. 8, and FIG. 9.

Referring now to FIG. 5, a sectional view of a protective housing containing a heat sink assembly for use in conjunction with an LED light bulb with an integrated heat sink in accordance with a preferred embodiment of the present invention comprises a protective casing or hoop 510. Protective casing or hoop 510 provides for additional protection for the LED light source and the remaining portions of the LED light bulb of the present invention.

Referring now to FIG. 6, a heat sink assembly for use in conjunction with an LED light bulb with an integrated heat sink in accordance with a preferred embodiment of the present invention is depicted with the outer portion of the case or housing removed, exposing the heat sink assembly. A pair of wire tubes or conduits 610, integrally formed with the casing, are shown in the interior space of the heat sink assembly. Additional descriptions concerning conduits 610 are presented below.

Referring now to FIG. 7, a top view of a collared connector 700 for use in conjunction with an LED light bulb with an integrated heat sink in accordance with a preferred embodiment of the present invention comprises a pair of wire openings 720, a pair of screw holes 710, and a plurality of alignment depressions 730. Alignment depressions 730 are used to align collared connector 700 with the case or housing of the LED light bulb of the present invention. Screw holes 710 are adapted to receive a fastener such as a screw, thereby allowing for assembly of the housing. Additionally, an alignment aperture 750 is provided to align with plug orientation pin 430 of FIG. 4.

Referring now to FIG. 8, a side view of a collared connector 700 for use in conjunction with an LED light bulb with an integrated heat sink in accordance with a preferred embodiment of the present invention comprises a substantially funnel-shaped body with a base portion 810.

Referring now to FIG. 9, an LED light bulb with an integrated heat sink in accordance with a preferred embodiment of the present invention comprises a housing 940 (shown in dashed lines), a pair of wire conduits or housings 910, and a pair of conductors or wires 920. Wire conduits 910 are integrally molded into the housing 940 and form a watertight housing for wires 920 to pass from the exterior of housing 940 into the interior space of housing 940 where they can be connected to the LED light source. The other end of wires 920 are connected to the power source for LED light bulb 100 of FIG. 1.

In this fashion, by utilizing an LED light source with an integrated heat sink, an LED light bulb may have the following advantages over the current state-of-the-art:
May last longer due to the reduced operating temperature.
May be more energy efficient than conventional incandescent lights.

From the foregoing description, it should be appreciated that an enhanced LED light bulb with an integrated heat sink is provided by the various preferred embodiments of the present invention and that the various preferred embodiments offer significant benefits that would be apparent to one skilled in the art. Furthermore, while multiple preferred embodiments have been presented in the foregoing description, it should be appreciated that a vast number of variations in the embodiments exist. Lastly, it should be appreciated that these embodiments are preferred exemplary embodiments only and are not intended to limit the scope, applicability, or configuration of the invention in any way. Rather, the foregoing detailed description provides those skilled in the art with a convenient road map for implementing a preferred exemplary embodiment of the invention, it being understood that various changes may be made in the function and arrangement of elements described in the exemplary preferred embodiment without departing from the spirit and scope of the invention as set forth in the appended claims.

1. An apparatus comprising
a housing with a compound parabolic concentrator configuration;
an LED light source contained within the housing; and
an integrated heat sink assembly.

2. The apparatus of claim 1 wherein the integrated heat sink assembly further comprises:
a plurality of heat sink vanes; and
a plurality of heat sink fins formed in the heat sink vanes, the heat sink fins being at substantially right angles to the heat sink vanes.

3. The apparatus of claim 2 wherein the integrated heat sink assembly comprises a plurality of heat sink vanes positioned in a substantially circular array around the LED light source, being positioned above and below the LED light source.

4. The apparatus of claim 1 further comprising:
a substantially funnel-shaped collared connector, the connector comprising a pair of wire conduits; and
a wire contained within each of the wire conduits.

5. The apparatus of claim 4 wherein the funnel-shaped connector comprises:
a plurality of alignment depressions;
a pair of screw holes; and
a pair of wire openings.
